(19) United States
(12) Patent Application Publication
(10) Pub. No.: US 2025/0273548 A1
(43) Pub. Date: Aug. 28, 2025

(54) PACKAGE COMPRISING A BRIDGE WITH SPRING PADS

(71) Applicant: QUALCOMM Incorporated, San Diego, CA (US)

(72) Inventors: Yangyang SUN, San Diego, CA (US); Dongming HE, San Diego, CA (US); Zhaozhi LI, San Diego, CA (US)

(21) Appl. No.: 18/590,030

(22) Filed: Feb. 28, 2024

(51) Int. Cl. H01L 23/498; H01L 21/48; H01L 23/00; H01L 23/538; H01L 25/065

(52) U.S. Cl. CPC H01L 23/49811; H01L 21/4853; H01L 23/49822; H01L 23/49827; H01L 23/5386; H01L 24/16; H01L 24/81; H01L 25/0655; H01L 2224/16227; H01L 2224/81815

(57) ABSTRACT

A package comprising a substrate; a first integrated device coupled to the substrate through at least a first plurality of solder interconnects; a second integrated device coupled to the substrate through at least a second plurality of solder interconnects; and a bridge coupled to the substrate, wherein the bridge comprises a plurality of spring pads.

### FIELD

Various features relate to packages with substrates, bridges, and integrated devices.

### BACKGROUND

A package may include a substrate and integrated devices. These components are coupled together to provide a package that may perform various electrical functions. There is an ongoing need to provide better performing packages. There is also an ongoing need to reduce the overall size of the packages.

### SUMMARY

Various features relate to packages with substrates, bridges, and integrated devices.

One example provides a package comprising a substrate; a first integrated device coupled to the substrate through at least a first plurality of solder interconnects; a second integrated device coupled to the substrate through at least a second plurality of solder interconnects; and a bridge coupled to the substrate, wherein the bridge comprises a plurality of spring pads.

Another example provides a method for fabricating a package. The method provides a substrate. The method couples a bridge coupled to the substrate, wherein the bridge comprises a plurality of spring pads. The method couples a first integrated device to the substrate through at least a first plurality of solder interconnects. The method couples a second integrated device to the substrate through at least a second plurality of solder interconnects.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that include a substrate, a bridge and integrated devices.

FIG. 2 illustrates a close up exemplary cross sectional profile view of a package that include a substrate, a bridge and integrated devices.

FIG. 3 illustrates an exemplary cross sectional profile view of a package that include a substrate, a bridge and integrated devices.

FIG. 4 illustrates a close up exemplary cross sectional profile view of a package that include a substrate, a bridge and integrated devices.

FIG. 5 illustrates an exemplary cross sectional profile view of a bridge that include spring pads.

FIG. 6 illustrates an exemplary cross sectional profile view of a bridge that include spring pads.

FIGS. 7A-7C illustrate different views of an exemplary spring pad.

FIGS. 8A-8C illustrate an exemplary sequence for fabricating a bridge comprising spring pads.

FIG. 9 illustrates an exemplary flow chart of a method for fabricating a bridge comprising spring pads.

FIGS. 10A-10D illustrate an exemplary sequence for fabricating a substrate.

FIGS. 11A-11B illustrate an exemplary sequence for fabricating a package that includes a substrate, a bridge and integrated devices.

FIG. 12 illustrates an exemplary flow chart of a method for fabricating a package that includes a substrate, a bridge and integrated devices.

FIG. 13 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a package comprising a substrate; a first integrated device coupled to the substrate through at least a first plurality of solder interconnects; a second integrated device coupled to the substrate through at least a second plurality of solder interconnects; and a bridge coupled to the substrate, wherein the bridge comprises a plurality of spring pads. As will be further described below, the package provides an effective configuration of a compact package with a bridge.

### Exemplary Package Comprising a Substrate, a Bridge and Integrated Devices

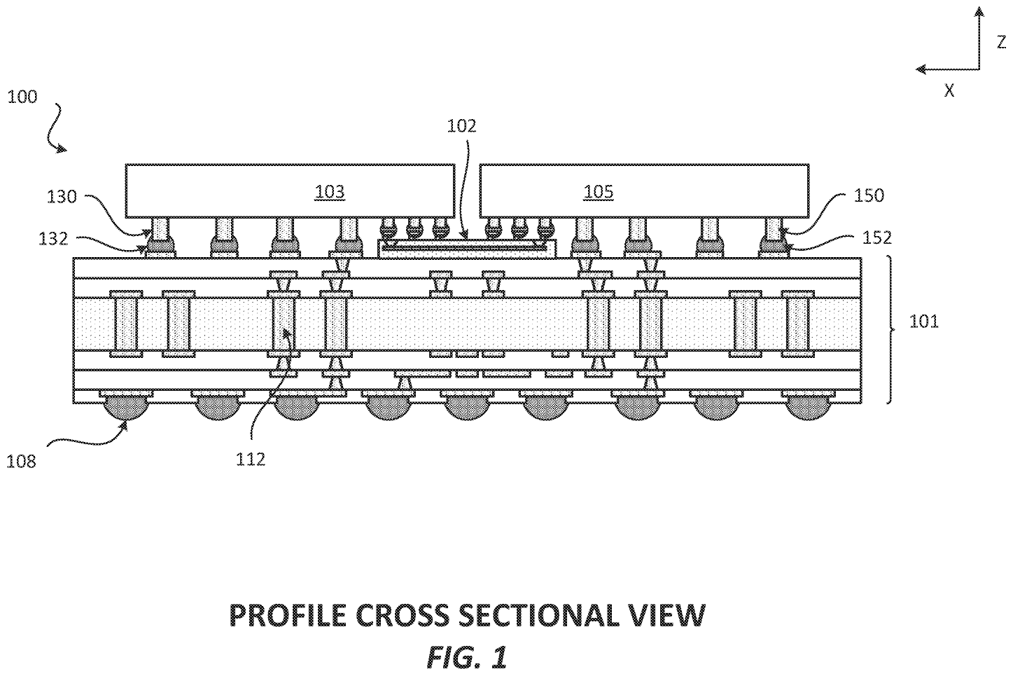

FIG. 1 illustrates a cross sectional profile view of a package 100 that includes a substrate, a bridge and integrated devices. The bridge includes spring pads. The package 100 includes a substrate 101, a bridge 102, an integrated device 103 and an integrated device 105. The integrated device 103 may be a first integrated device. The integrated device 105 may be a second integrated device.

The substrate 101 includes a core layer, a plurality of dielectric layers and a plurality of interconnects 112. A plurality of solder interconnects 108 are coupled to the substrate 101. The bridge 102 is coupled to a surface (e.g., first surface, top surface) of the substrate 101. The integrated device 103 is coupled to the substrate 101 through a plurality of pillar interconnects 130 and a plurality of solder interconnects 132. The integrated device 105 is coupled to the substrate 101 through a plurality of pillar interconnects 150 and a plurality of solder interconnects 152. The integrated device 103 is coupled to the bridge 102 through pillar interconnects from the plurality of pillar interconnects 130 and solder interconnects from the plurality of solder interconnects 132. The integrated device 105 is coupled to the bridge 102 through pillar interconnects from the plurality of pillar interconnects 150 and solder interconnects from the plurality of solder interconnects 152. In some implementations, an electrical path between the integrated device 103 and the integrated device 105 may include the bridge 102.

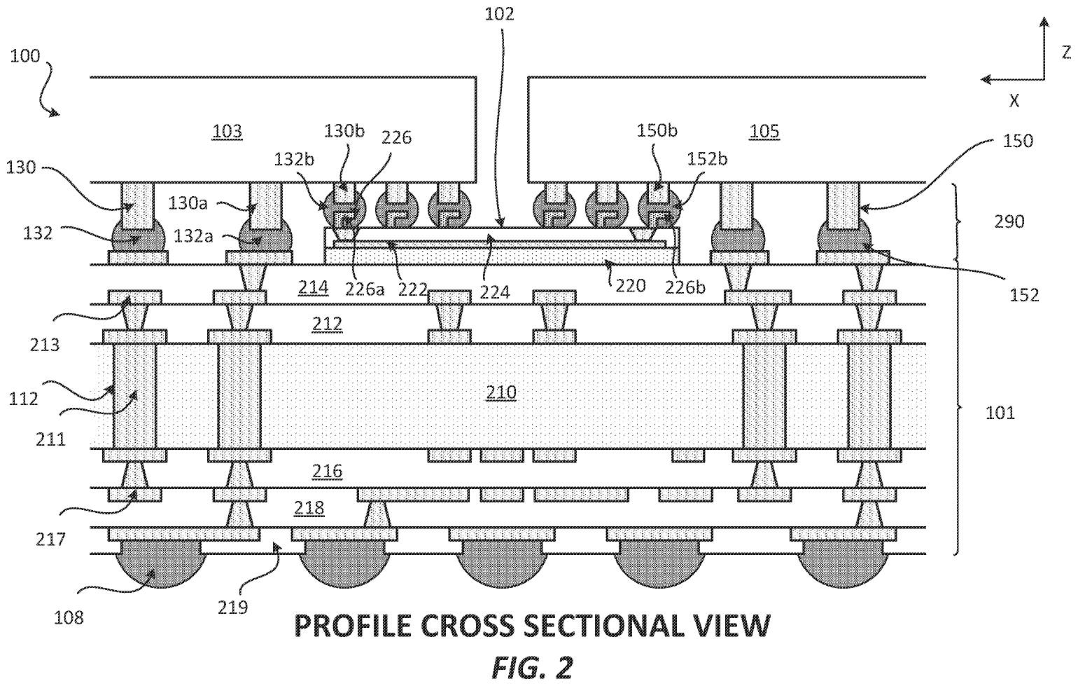

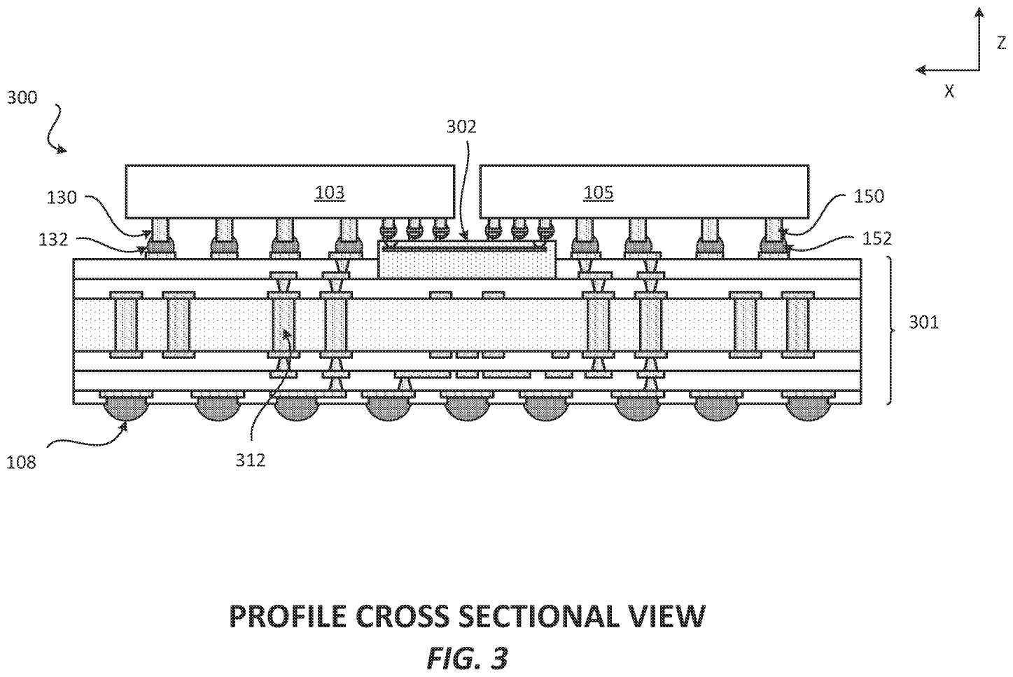

As will be further described below in at least FIG. 2, the bridge 102 includes a plurality of spring pads. The plurality of spring pads of the bridge 102 allow for low cost high density connections between integrated devices. Moreover, the plurality of spring pads may help reduce the assembly cycle time of the package. The use of the bridge 102 with spring pads, allows for a more compact package 100. For example, the overall thickness of the package 100 may be reduced because the distance, the gap and/or the space between the integrated device (e.g., 103, 105) and the substrate 101 may be reduced. In some implementations, the distance, the gap and/or the space between the front side of the integrated device (e.g., 103, 105) and the top surface of the substrate 101, may be about 60 micrometers. In some implementations, as will be further described below in at least FIG. 3, a bridge with the spring pads may be embedded in the substrate, while the distance, the gap and/or the space between the front side of the integrated device (e.g., 103, 105) and the top surface of the substrate 101, may be about 60 micrometers.

FIG. 2 illustrates a close up view of the package 100 that includes a substrate, a bridge and integrated devices. The substrate 101 includes a core layer 210, a dielectric layer 212, a dielectric layer 214, a dielectric layer 216, a dielectric layer 218, a plurality of interconnects 211, a plurality of interconnects 213 and a plurality of interconnects 217. The plurality of interconnects 112 may represent the plurality of interconnects 211, the plurality of interconnects 213 and/or the plurality of interconnects 217. The core layer 210 may include a core dielectric layer. The core layer 210 may include different or similar materials as the a dielectric layer 212, the dielectric layer 214, the dielectric layer 216, and/or the dielectric layer 218. The dielectric layer 212 is coupled to a first surface of the core layer 210. The dielectric layer 214 is coupled to the dielectric layer 212. The dielectric layer 212 and the dielectric layer 214 may considered part of the same dielectric layer. The dielectric layer 216 is coupled to a second surface of the core layer 210. The dielectric layer 218 is coupled to the dielectric layer 216. The dielectric layer 216 and the dielectric layer 218 may considered part of the same dielectric layer. The dielectric layer 212, the dielectric layer 214, the dielectric layer 216 and/or the dielectric layer 218 may include prepreg. The substrate 101 also includes a solder resist layer 219.

The plurality of interconnects 211 may be located in the core layer 210. The plurality of interconnects 211 may include a plurality of core interconnects (e.g., core via interconnects, via interconnects). The plurality of interconnects 213 may be located at least in the dielectric layer 212 and/or the dielectric layer 214. The plurality of interconnects 213 may include interconnects located on a surface of the dielectric layer 214. The plurality of interconnects 213 may be coupled to the plurality of interconnects 211. The plurality of interconnects 217 may be located at least in the dielectric layer 216 and/or the dielectric layer 218. The plurality of interconnects 217 may include interconnects located on a surface of the dielectric layer 218. The plurality of interconnects 217 may be coupled to the plurality of interconnects 211. A plurality of solder interconnects 108 may be coupled to the plurality of interconnects 217.

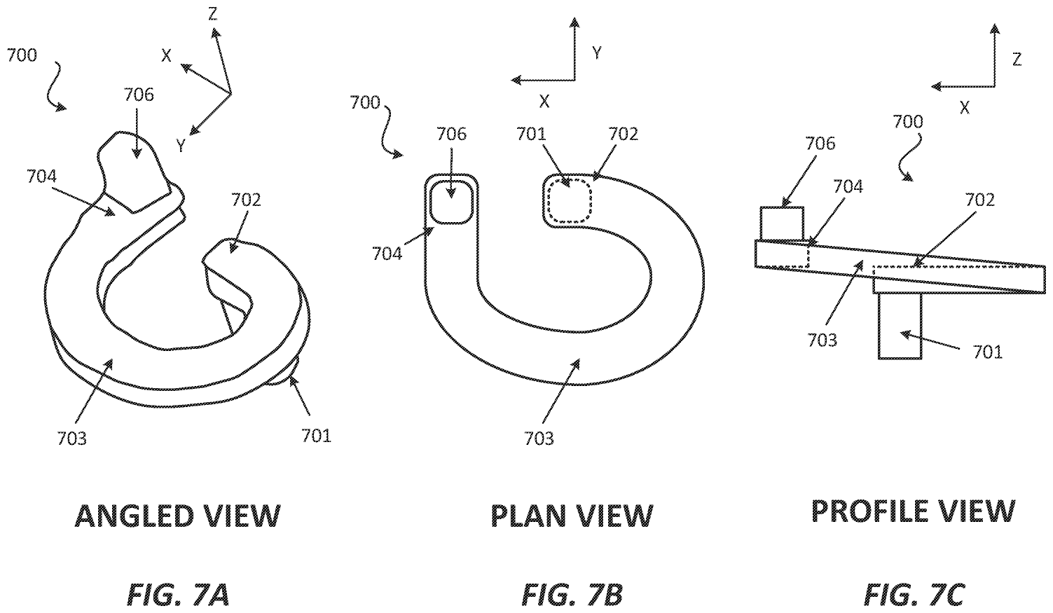

The bridge 102 includes a bridge substrate 220, a plurality of bridge interconnects 222, and a bridge dielectric layer 224. The plurality of bridge interconnects 222 may include a plurality of spring pads 226. The bridge substrate 220 may include a silicon substrate. The plurality of bridge interconnects 222 may include traces, pads and/or vias. The plurality of bridge interconnects 222 may have pitches that are lower and/or less than the pitches of the plurality of interconnects 213, the plurality of interconnects 211 and/or the plurality of interconnects 217. The plurality of spring pads 226 may include pads that are flexible and/or bend under load. The use of the plurality of spring pads 226 may help provide a package that are thinner and/or more compact. Since the plurality of spring pads 226 have built in flex in them, the tolerance in the height and/or thickness of the bridge 102 can be smaller, while still ensuring that there is proper joint connection and/or coupling between the bridge 102 and the integrated device 103 and/or the integrated device 105. In some implementations, the distance, the gap and/or the space 290 between the integrated device 103 and a surface of the substrate 101 may be about 60 micrometers or less. In some implementations, the distance, the gap and/or the space 290 between the integrated device 105 and a surface of the substrate 101 may be about 60 micrometers or less. However, the distance, the gap and/or the space 290 may be greater than 60 micrometers. Different implementations of the plurality of spring pads 226 may vertically flex and/or vertically bend differently. In some implementations, portions of the plurality of spring pads 226 may be configured to be able to vertically bend and/or vertically flex by at least 1 micrometer. In some implementations, portions of the plurality of spring pads 226 may be configured to be able to vertically bend and/or vertically flex by at least 2 micrometers. In some implementations, portions of the plurality of spring pads 226 may be configured to be able to vertically bend and/or vertically flex by at least 3 micrometers. The plurality of spring pads 226 may have different shapes and/or sizes. In some implementations, one or more spring pads from the plurality of spring pads 226 may have a spring shape. In some implementations, one or more spring pads from the plurality of spring pads 226 may have a helix shape (e.g., partial helix shape). As will be further illustrated and described below in at least FIGS. 7A-7C, a helix shape may curve and/or spiral upwards and/or downwards. In some implementations, one or more spring pads from the plurality of spring pads 226 may have a G-helix shape. The bridge 102 may be coupled to a surface of the substrate 101. For example, the bridge substrate 220 may be coupled to the dielectric layer 214. In some implementations, an adhesive (not shown) may be used to couple the backs side of the bridge substrate 220 of the bridge 102 to a surface of the dielectric layer 214 of the substrate 101. Thus, the bridge 102 may or may not touch the dielectric layer 214 of the substrate 101. In some implementations, a solder resist layer (not shown) may be coupled to the dielectric layer 214. In such instances, the bridge 102 may be coupled to a solder resist layer of the substrate 101.

The integrated device 103 may be coupled to the substrate 101 through (i) a pillar interconnect 130a from the plurality of pillar interconnects 130 and (ii) a solder interconnect 132a from the plurality of solder interconnects 132. The solder interconnect 132a may be coupled to an interconnect from the plurality of interconnects 213. The solder interconnect 132a may touch an interconnect from the plurality of interconnects 213. The integrated device 103 may be coupled to the bridge 102 through (i) a pillar interconnect 130b from the plurality of pillar interconnects 130 and (ii) a solder interconnect 132b from the plurality of solder interconnects 132. The solder interconnect 132b may be coupled to and touch a spring pad 226a from the plurality of spring pads 226. The pillar interconnect 130b is shorter than the pillar interconnect 130a.

The integrated device 105 may be coupled to the substrate 101 through (i) a pillar interconnect 150a from the plurality of pillar interconnects 150 and (ii) a solder interconnect 152a from the plurality of solder interconnects 152. The solder interconnect 152a may be coupled to an interconnect from the plurality of interconnects 213. The solder interconnect 152a may touch an interconnect from the plurality of interconnects 213. The integrated device 105 may be coupled to the bridge 102 through (i) a pillar interconnect 150b from the plurality of pillar interconnects 150 and (ii) a solder interconnect 152b from the plurality of solder interconnects 152. The solder interconnect 152b may be coupled to and touch a spring pad 226b from the plurality of spring pads 226. The pillar interconnect 150b is shorter than the pillar interconnect 150a.

An electrical path between the integrated device 103 and the integrated device 105 may include the bridge 102. For example, an electrical path between the integrated device 103 and the integrated device 105 may include a pillar interconnect 130b, a solder interconnect 132b, a spring pad 226a, at least one bridge interconnect from the plurality of bridge interconnects 222, a spring pad 226b, a solder interconnect 152b and/or a pillar interconnect 150b.

In some implementations, a bridge may be at least partially embedded in the substrate. FIG. 3 illustrates a cross sectional profile view of a package 300 that includes a substrate, a bridge and integrated devices. The bridge includes spring pads. The package 300 includes a substrate 301, a bridge 302, an integrated device 103 and an integrated device 105. The integrated device 103 may be a first integrated device. The integrated device 105 may be a second integrated device. The package 300 is similar to the package 100. However, the package 300 includes a bridge that is at least partially embedded in the substrate.

The substrate 301 includes a core layer, a plurality of dielectric layers and a plurality of interconnects 312. A plurality of solder interconnects 108 are coupled to the substrate 301. The bridge 302 is at least partially embedded in the substrate 301. The integrated device 103 is coupled to the substrate 301 through a plurality of pillar interconnects 130 and a plurality of solder interconnects 132. The integrated device 105 is coupled to the substrate 301 through a plurality of pillar interconnects 150 and a plurality of solder interconnects 152. The integrated device 103 is coupled to the bridge 302 through pillar interconnects from the plurality of pillar interconnects 130 and solder interconnects from the plurality of solder interconnects 132. The integrated device 105 is coupled to the bridge 302 through pillar interconnects from the plurality of pillar interconnects 150 and solder interconnects from the plurality of solder interconnects 152. In some implementations, an electrical path between the integrated device 103 and the integrated device 105 may include the bridge 302.

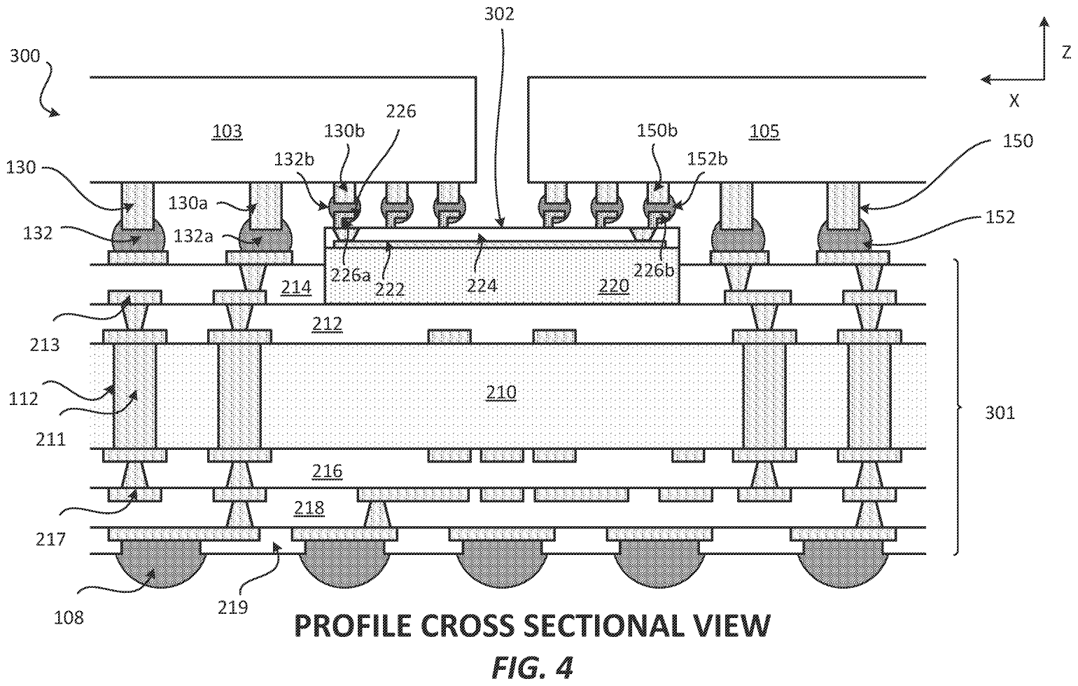

As will be further described below in at least FIG. 4, the bridge 302 includes a plurality of spring pads. The plurality of spring pads of the bridge 302 allow for low cost high density connections between integrated devices. Moreover, the plurality of spring pads may help reduce the assembly cycle time of the package. The use of the bridge 302 with spring pads, allows for a more compact package 300. For example, the overall thickness of the package 300 may be reduced because the distance, the gap and/or the space between the integrated device (e.g., 103, 105) and the substrate 301 may be reduced. In some implementations, the distance, the gap and/or the space between the front side of the integrated device (e.g., 103, 105) and the top surface of the substrate 301, may be about 60 micrometers.

FIG. 4 illustrates a close up view of the package 300 that includes a substrate, a bridge and integrated devices. The substrate 301 includes a core layer 210, a dielectric layer 212, a dielectric layer 214, a dielectric layer 216, a dielectric layer 218, a plurality of interconnects 211, a plurality of interconnects 213 and a plurality of interconnects 217. The plurality of interconnects 312 may represent the plurality of interconnects 211, the plurality of interconnects 213 and/or the plurality of interconnects 217. The core layer 210 may include a core dielectric layer. The core layer 210 may include different or similar materials as the a dielectric layer 212, the dielectric layer 214, the dielectric layer 216, and/or the dielectric layer 218. The dielectric layer 212 is coupled to a first surface of the core layer 210. The dielectric layer 214 is coupled to the dielectric layer 212. The dielectric layer 212 and the dielectric layer 214 may considered part of the same dielectric layer. The dielectric layer 216 is coupled to a second surface of the core layer 210. The dielectric layer 218 is coupled to the dielectric layer 216. The dielectric layer 216 and the dielectric layer 218 may considered part of the same dielectric layer. The dielectric layer 212, the dielectric layer 214, the dielectric layer 216 and/or the dielectric layer 218 may include prepreg. The substrate 301 also includes a solder resist layer 219.

The plurality of interconnects 211 may be located in the core layer 210. The plurality of interconnects 211 may include a plurality of core interconnects (e.g., core via interconnects, via interconnects). The plurality of interconnects 213 may be located at least in the dielectric layer 212 and/or the dielectric layer 214. The plurality of interconnects 213 may include interconnects located on a surface of the dielectric layer 214. The plurality of interconnects 213 may be coupled to the plurality of interconnects 211. The plurality of interconnects 217 may be located at least in the dielectric layer 216 and/or the dielectric layer 218. The plurality of interconnects 217 may include interconnects located on a surface of the dielectric layer 218. The plurality of interconnects 217 may be coupled to the plurality of interconnects 211. A plurality of solder interconnects 108 may be coupled to the plurality of interconnects 217.

The bridge 302 includes a bridge substrate 220, a plurality of bridge interconnects 222, and a bridge dielectric layer 224. The plurality of bridge interconnects 222 may include a plurality of spring pads 226. The bridge substrate 220 may include a silicon substrate. The plurality of bridge interconnects 222 may include traces, pads and/or vias. The plurality of bridge interconnects 222 may have pitches that are lower and/or less than the pitches of the plurality of interconnects 213, the plurality of interconnects 211 and/or the plurality of interconnects 217. The plurality of spring pads 226 may include pads that are flexible and/or bend under load. The use of the plurality of spring pads 226 may help provide packages that are thinner and/or more compact. Since the plurality of spring pads 226 have built in flex in them, the tolerance in the height and/or thickness of the bridge 302 can be smaller, while still ensuring that there is proper joint connection and/or coupling between the bridge 302 and the integrated device 103 and/or the integrated device 105. In some implementations, the gap and/or space 290 between the integrated device 103 and a surface of the substrate 301 may be about 60 micrometers or less. In some implementations, the gap and/or space 290 between the integrated device 105 and a surface of the substrate 301 may be about 60 micrometers or less. Different implementations of the plurality of spring pads 226 may vertically flex and/or vertically bend differently. In some implementations, portions of the plurality of spring pads 226 may be configured to be able to vertically bend and/or vertically flex by at least 1 micrometer. In some implementations, portions of the plurality of spring pads 226 may be configured to be able to vertically bend and/or vertically flex by at least 2 micrometers. In some implementations, portions of the plurality of spring pads 226 may be configured to be able to vertically bend and/or vertically flex by at least 3 micrometers. The plurality of spring pads 226 may have different shapes and/or sizes. In some implementations, one or more spring pads from the plurality of spring pads 226 may have a spring shape. In some implementations, one or more spring pads from the plurality of spring pads 226 may have a helix shape (e.g., partial helix shape). In some implementations, one or more spring pads from the plurality of spring pads 226 may have a G-helix shape.

The bridge 302 may be at least partially embedded in the substrate 301. For example, the bridge substrate 220 may be at least partially embedded in the dielectric layer 214. In some implementations, an adhesive (not shown) may be used to couple the bridge substrate 220 of the bridge 302 to a the dielectric layer 214 of the substrate 301. The bridge 302 may or may not touch the dielectric layer 214 of the substrate 301. A side surface of the bridge 302 may touch the dielectric layer 214. For example, a side surface of the bridge dielectric layer 224 and/or a side surface of the bridge substrate 220 may touch the dielectric layer 214.

The integrated device 103 may be coupled to the substrate 301 through (i) a pillar interconnect 130a from the plurality of pillar interconnects 130 and (ii) a solder interconnect 132a from the plurality of solder interconnects 132. The solder interconnect 132a may be coupled to an interconnect from the plurality of interconnects 213. The solder interconnect 132a may touch an interconnect from the plurality of interconnects 213. The integrated device 103 may be coupled to the bridge 302 through a pillar interconnect 130b from the plurality of pillar interconnects 130 and a solder interconnect 132b from the plurality of solder interconnects 132. The solder interconnect 132b may be coupled to a spring pad 226a from the plurality of spring pads 226.

The integrated device 105 may be coupled to the substrate 301 through (i) a pillar interconnect 150a from the plurality of pillar interconnects 150 and (ii) a solder interconnect 152a from the plurality of solder interconnects 152. The solder interconnect 152a may be coupled to an interconnect from the plurality of interconnects 213. The solder interconnect 152a may touch an interconnect from the plurality of interconnects 213. The integrated device 105 may be coupled to the bridge 302 through (i) a pillar interconnect 150b from the plurality of pillar interconnects 150 and (ii) a solder interconnect 152b from the plurality of solder interconnects 152. The solder interconnect 152b may be coupled to a spring pad 226b from the plurality of spring pads 226.

An electrical path between the integrated device 103 and the integrated device 105 may include the bridge 302. For example, an electrical path between the integrated device 103 and the integrated device 105 may include a pillar interconnect 130b, a solder interconnect 132b, a spring pad 226a, at least one bridge interconnect from the plurality of bridge interconnects 222, a spring pad 226b, a solder interconnect 152b and/or a pillar interconnect 150b.

In some implementations, the bridge (e.g., 102, 302) may have a thickness of about 40 micrometers or greater. In some implementations, the overall combined height of the pillar interconnect 130a and the solder interconnect 132a may be about in a range of 40-100 micrometers. The pitch of the pillar interconnects 130a may be in a range of about 60-100 micrometers. In some implementations, the overall minimum combined height of the pillar interconnect 130b and the solder interconnect 132b may be about 10 micrometers or greater. The minimum pitch of the pillar interconnects 130b may be about 20 micrometers or greater. In some implementations, the overall combined height of the pillar interconnect 150a and the solder interconnect 152a may be about in a range of 40-100 micrometers. The pitch of the pillar interconnects 150a may be in a range of about 60-100 micrometers. In some implementations, the overall minimum combined height of the pillar interconnect 150b and the solder interconnect 152b may be about 10 micrometers or greater. The minimum pitch of the pillar interconnects 150b may be about 20 micrometers or greater.

The package (e.g., 100, 300) may include an underfill and/or an encapsulation layer between the integrated device(s) and the substrate. For example, an underfill (or an encapsulation layer) may be located (i) between the integrated device 103 and the substrate (e.g., 101, 301), (ii) between the integrated device 103 and the bridge (e.g., 102, 302), (iii) between the integrated device 105 and the substrate (e.g., 101, 301), (iv) between the integrated device 105 and the bridge (e.g., 102, 302), and/or (v) between the integrated device 103 and the integrated device 105. The underfill or the encapsulation may be coupled to and touch the plurality of spring pads 226. FIGS. 1-4 illustrate examples of a package that includes a cored substrate. However, other types of substrates may be used in the package, such as a coreless substrate, including an embedded trace substrate (ETS).

### Exemplary Bridge Comprising Spring Pads

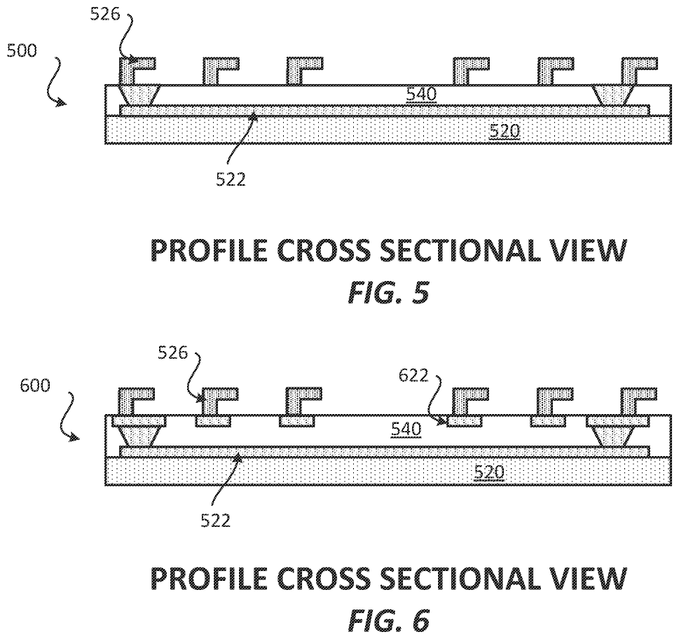

FIG. 5 illustrates an example of a bridge 500 that includes spring pads. The bridge 500 may represent the bridge 102 and/or the bridge 302. The bridge 500 includes a bridge substrate 520, a plurality of bridge interconnects 522, a bridge dielectric layer 540 and a plurality of spring pads 526. The plurality of spring pads 526 may considered part of the plurality of bridge interconnects 522. The plurality of bridge interconnects 522 may include bridge interconnects located on a surface of the bridge substrate 520 and/or bridge interconnects located in the bridge dielectric layer 540. Examples of bridge interconnects that are located in the bridge dielectric layer 540 include bridge interconnects and/or bridge via interconnects. The plurality of spring pads 526 may be coupled to the plurality of bridge interconnects 522. The plurality of spring pads 526 may be coupled to via interconnects from the plurality of bridge interconnects 522. The plurality of spring pads 526 may be located above the bridge dielectric layer 540. A detailed example of a spring pad is further described below in at least FIGS. 7A-7C.

FIG. 6 illustrates an example of a bridge 600 that includes spring pads. The bridge 600 may represent the bridge 102 and/or the bridge 302. The bridge 600 may be similar to the bridge 500. The bridge 600 includes a bridge substrate 520, a plurality of bridge interconnects 522, a plurality of bridge interconnects 622, a bridge dielectric layer 540 and a plurality of spring pads 526. The plurality of spring pads 526 and/or the plurality of bridge interconnects 633 may considered part of the plurality of bridge interconnects 522. The plurality of bridge interconnects 522 may include bridge interconnects located on a surface of the bridge substrate 520 and/or bridge interconnects located in the bridge dielectric layer 540. Examples of bridge interconnects that are located in the bridge dielectric layer 540 include bridge interconnects, bridge pad interconnects and/or bridge via interconnects. The plurality of bridge interconnects 622 may include bridge pad interconnects and/or bridge trace interconnects. The plurality of spring pads 526 may be coupled to the plurality of bridge interconnects 622. The plurality of spring pads 526 may be coupled to bridge pad interconnects from the plurality of bridge interconnects 622. The plurality of spring pads 526 may be located above the bridge dielectric layer 540. A detailed example of a spring pad is further described below in at least FIGS. 7A-7C.

FIGS. 7A-7C illustrate various views of an example of a spring pad 700. FIG. 7A illustrates an exemplary angled view of an example of a spring pad 700. FIG. 7A illustrates an exemplary plan view of an example of a spring pad 700. FIG. 7C illustrates an exemplary profile view of an example of a spring pad 700. The spring pad 700 may represent any of the spring pads described in the disclosure. For example, the spring pad 700 may represent the spring pad 700 may represent the spring pad 226 and/or the spring pad 526. The spring pad 700 may have a spring shape. The spring pad 700 may have a helix shape (e.g., partial helix shape). The spring pad 700 may have a G-helix shape. It is noted that the use of the term helix shape in the disclosure, shall also include to mean a partial helix shape. A helix shape may curve and/or spiral upwards and/or downward. In some implementations, the spring pad 700 may have approximately 1 or less turns. In some implementations, the spring pad 700 may curve along a planar cross section (e.g., X-Y plane), with little or no vertical curve (e.g., little or no vertical offset in Z direction).

The spring pad 700 includes a portion 702, a portion 703 and a portion 704. The spring pad 700 may also include the post 701 and the vertical post 706. The portion 703 may be coupled to the portion 702 and the portion 704. The post 701 may be coupled to the portion 702. The post 701 may be a vertical post. The vertical post 706 may be coupled to the portion 704. The post 701, the portion 702, the portion 703, the portion 704 and/or the vertical post 706 may be a continuous and/or contiguous spring pad. In some implementations, the portion 702 and the portion 704 may be lateral to each other. In some implementations, the portion 702 and the portion 704 may be partially lateral to each other. In some implementations, the portion 704 may be located vertically farther away from the bridge than the portion 702 is located from the bridge.

A portion of the spring pad 700 may be configured to vertically flex and/or vertically bend. Different implementations of the spring pad 700 may vertically flex and/or vertically flex differently. Different portions of the spring pad 700 may flex and/or bend vertically by different values. For example, a first portion of the spring pad 700 may flex and/or bend vertically by a first value, while a second portion of the spring pad 700 may flex and/or bend vertically by a second value. In some implementations, the portion 702 of the spring pad 700 may vertically flex very little or not at all, while the portion 704 of the spring pad 700 may vertically flex relatively more. In some implementations, the spring pad 700 may include a vertical post 706 that extends from the portion 704 of the spring pad 700. The vertical post 706 may be configured to be coupled to solder interconnect. In some implementations, the spring pad 700 also include a post 701. The post 701 may be coupled to the portion 702 of the spring pad 700. In some implementations, the post 701 may be configured to be coupled to a bridge interconnect (e.g., bridge via interconnect) of a bridge (e.g., 102, 302, 500, 600).

The heights of the vertical post 706 and/or the post 701 may vary with different implementations. The vertical post 706 and/or the post 701 may be optional. In some implementations, the post 701 may be coupled to a bridge interconnect of a bridge. In some implementations, the portion 702 is coupled to a bridge interconnect of a bridge. In some implementations, a solder interconnect (e.g., 132b, 152b) may be coupled to the portion 704 and/or the vertical post 706. FIGS. 7A-7C illustrates that a solder interconnect may be coupled to and touching the vertical post 706, which is offset to the post 701 (which is coupled to a bridge interconnect). Thus, the solder interconnect that is coupled to the spring pad 700, may be offset to the bridge interconnect that is coupled to and touching the spring pad 700.

An integrated device (e.g., 103, 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 300) may be implemented in a radio frequency (RF) package. The RF package may be a radio frequency front end (RFFE) package. A package (e.g., 100, 300) may be configured to provide Wireless Fidelity (WiFi) communication and/or cellular communication (e.g., 2G, 3G, 4G, 5G). The packages (e.g., 100, 300, 400) may be configured to support Global System for Mobile (GSM) Communications, Universal Mobile Telecommunications System (UMTS), and/or Long-Term Evolution (LTE). The packages (e.g., 100, 300) may be configured to transmit and receive signals having different frequencies and/or communication protocols.

Having described various packages, a sequence for fabricating a package will now be described below.

### Exemplary Sequence for Fabricating a Bridge Comprising Spring Pads

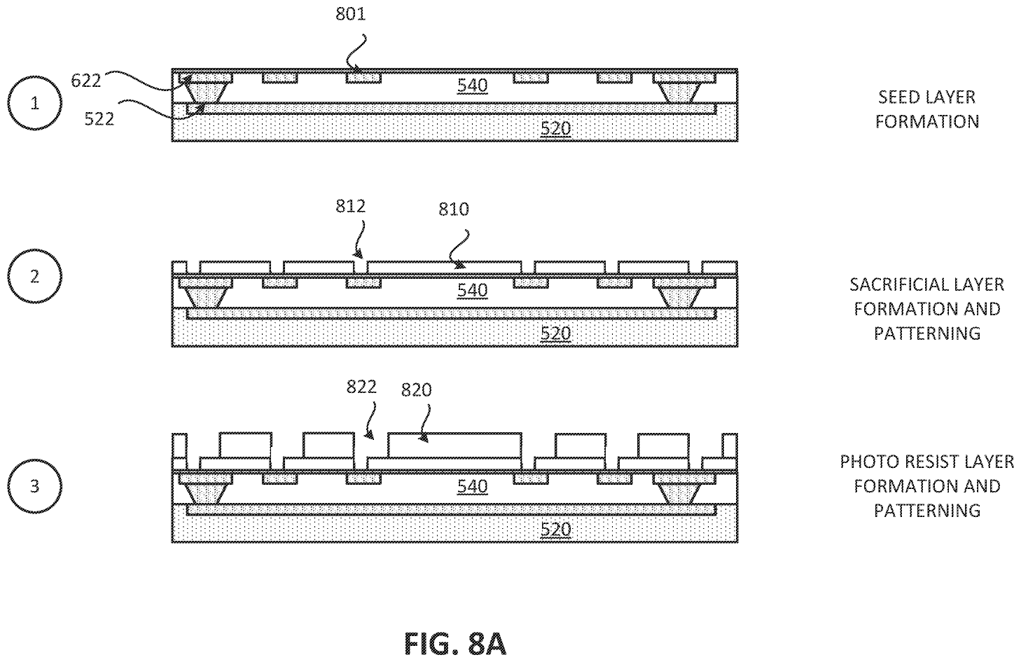

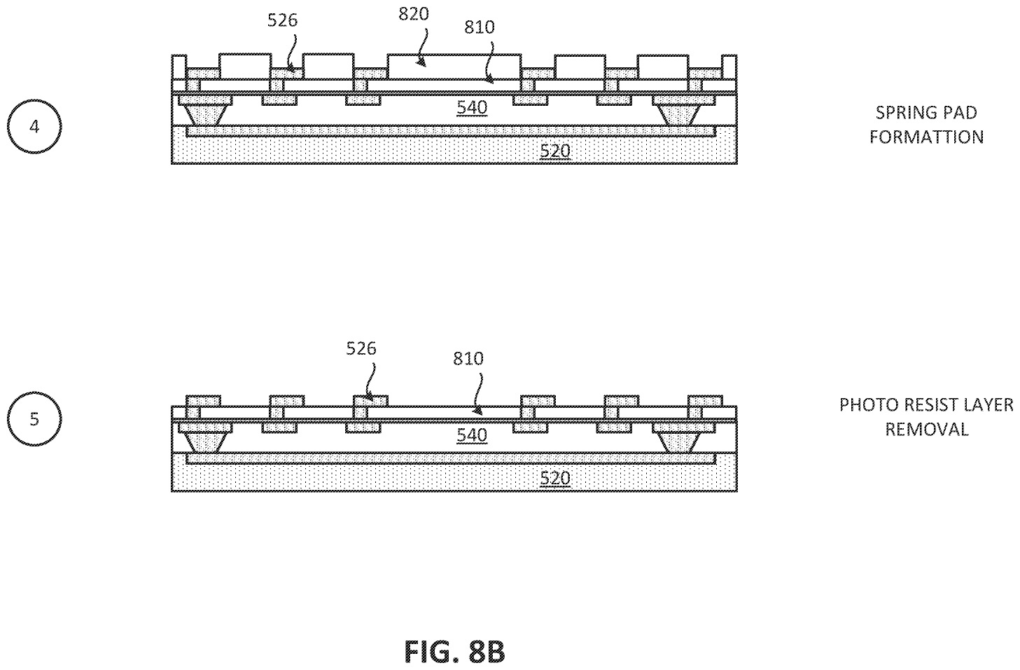

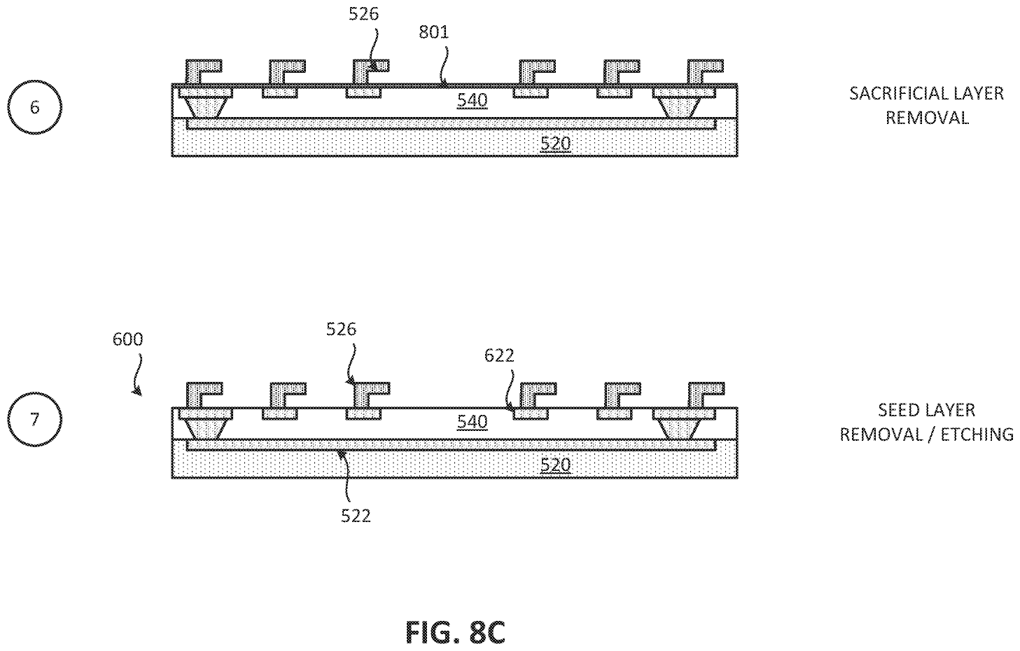

In some implementations, fabricating a bridge includes several processes. FIGS. 8A-8C illustrate an exemplary sequence for providing or fabricating a bridge. In some implementations, the sequence of FIGS. 8A-8C may be used to provide or fabricate the bridge 600. However, the process of FIGS. 8A-8C may be used to fabricate any of the bridges (e.g., 102, 302, 500, 600) described in the disclosure.

It should be noted that the sequence of FIGS. 8A-8C may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.
Stage 1, as shown in FIG. 8A, illustrates a state after a bridge substrate 520, a plurality of bridge interconnects 522, a plurality of bridge interconnects 622, a bridge dielectric layer 540 and a seed layer 801 are provided. The bridge substrate 520 may include a silicon substrate. The plurality of bridge interconnects 522, the plurality of bridge interconnects 622, the bridge dielectric layer 540 and the seed layer 801 may be fabricated and/or formed over the bridge substrate 520. A plating process may be used to form the plurality of bridge interconnects 522 and/or the plurality of bridge interconnects 622. A deposition process and/or a lamination process may be used to form the bridge dielectric layer 540. The bridge dielectric layer 540 may include prepreg. The seed layer 801 is formed over the plurality of bridge interconnects 622 and the bridge dielectric layer 540. A plating process may be used to form the seed layer 801.
Stage 2 illustrates a state after a sacrificial layer 810 is formed and patterned. The sacrificial layer 810 may be formed over the seed layer 801. The patterning of the sacrificial layer 810 may form openings 812 in the sacrificial layer 810. The sacrificial layer 810 may include a photo resist layer. A deposition process may be used to form the sacrificial layer 810. An exposure process and/or a developing process may be used to form the openings 812 in the sacrificial layer 810.
Stage 3 illustrates a photo resist layer 820 is formed and patterned. The photo resist layer 820 may be formed over the sacrificial layer 810. The patterning of the photo resist layer 820 may form openings 822 in the photo resist layer 820. The photo resist layer 820 may include a photo resist layer that is different from the sacrificial layer 810. For example, the sacrificial layer 810 may include a first photo resist layer that is different from the photo resist layer 820. A deposition process may be used to form the photo resist layer 820. An exposure process and/or a developing process may be used to form the openings 822 in the photo resist layer 810.
Stage 4, as shown in FIG. 8B, illustrates a state after a plurality of spring pads 526 are formed. The plurality of spring pads 526 may be formed in the openings 812 of the sacrificial layer 810 and the openings 822 of the photo resist layer 820. A plating process may be used to form the plurality of spring pads 526. The plurality of spring pads 526 are coupled to the seed layer 801. The plurality of spring pads 526 may have a spring shape. The plurality of spring pads 526 may have a helix shape (e.g., partial helix shape). The plurality of spring pads 526 may have a G-helix shape. The plurality of spring pads 526 may be configurable to have vertical flex and/or vertical bend.
Stage 5 illustrates a state after the photo resist layer 820 is removed. A photo resist removal process may be used to remove the photo resist layer 820.
Stage 6, as shown in FIG. 8C, illustrates a state after the sacrificial layer 810 is removed. A photo resist removal process may be used to remove the sacrificial layer 810.
Stage 7 illustrates a state after portions of the seed layer 801 are removed. An etching process may be used to remove portions of the seed layer 801. The remaining seed layer 801 may considered part of the plurality of spring pads 526 and/or the plurality of bridge interconnects 622.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Bridge Comprising Spring Pads

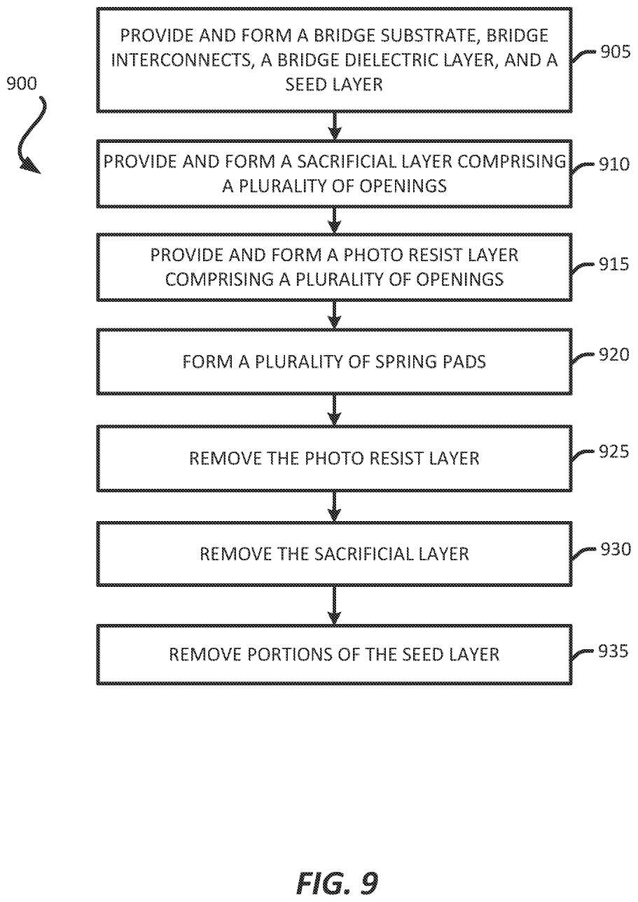

In some implementations, fabricating a bridge includes several processes. FIG. 9 illustrates an exemplary flow diagram of a method 900 for providing or fabricating a bridge. In some implementations, the method 900 of FIG. 9 may be used to provide or fabricate the bridge 600 described in the disclosure. However, the method 900 may be used to provide or fabricate any of the bridges (e.g., 102, 302, 500) described in the disclosure.

It should be noted that the method 900 of FIG. 9 may combine one or more processes in order to simplify and/or clarify the method for providing or fabricating a bridge. In some implementations, the order of the processes may be changed or modified.

The method provides and/or forms (at 905) a bridge substrate, a plurality of bridge interconnects, a bridge dielectric layer and a seed layer. Stage 1 of FIG. 8A, illustrates and describes an example of a state after a bridge substrate 520, a plurality of bridge interconnects 522, a plurality of bridge interconnects 622, a bridge dielectric layer 540 and a seed layer 801 are provided. The bridge substrate 520 may include a silicon substrate. The plurality of bridge interconnects 522, the plurality of bridge interconnects 622, the bridge dielectric layer 540 and the seed layer 801 may be fabricated and/or formed over the bridge substrate 520. A plating process may be used to form the plurality of bridge interconnects 522 and/or the plurality of bridge interconnects 622. A deposition process may be used to form the bridge dielectric layer 540. The bridge dielectric layer 540 may include prepreg. The seed layer 801 is formed over the plurality of bridge interconnects 622 and the bridge dielectric layer 540. A plating process may be used to form the seed layer 801.

The method provides and forms (at 910) a sacrificial layer comprising a plurality of openings. Stage 2 of FIG. 8A, illustrates and describes an example of a state after a sacrificial layer 810 is formed and patterned. The sacrificial layer 810 may be formed over the seed layer 801. The patterning of the sacrificial layer 810 may form openings 812 in the sacrificial layer 810. The sacrificial layer 810 may include a photo resist layer. A deposition process and/or a lamination process may be used to form the sacrificial layer 810. An exposure process and/or a developing process may be used to form the openings 812 in the sacrificial layer 810.

The method provides and forms (at 915) a photo resist layer comprising a plurality of openings. Stage 3 of FIG. 8A, illustrates and describes an example of a photo resist layer 820 is formed and patterned. The photo resist layer 820 may be formed over the sacrificial layer 810. The patterning of the photo resist layer 820 may form openings 822 in the photo resist layer 820. The photo resist layer 820 may include a photo resist layer that is different from the sacrificial layer 810. For example, the sacrificial layer 810 may include a first photo resist layer that is different from the photo resist layer 820. A deposition process may be used to form the photo resist layer 820. An exposure process and/or a developing process may be used to form the openings 822 in the photo resist layer 820.

The method forms (at 920) a plurality of spring pads. Stage 4 of FIG. 8B, illustrates and describes an example of a state after a plurality of spring pads 526 are formed. The plurality of spring pads 526 may be formed in the openings 812 of the sacrificial layer 810 and the openings 822 of the photo resist layer 820. A plating process may be used to form the plurality of spring pads 526. The plurality of spring pads 526 are coupled to the seed layer 801. The plurality of spring pads 526 may have a spring shape. The plurality of spring pads 526 may have a helix shape (e.g., partial helix shape). The plurality of spring pads 526 may have a G-helix shape. The plurality of spring pads 526 may be configurable to have vertical flex and/or vertical bend.

The method removes (at 925) the photo resist layer. Stage 5 of FIG. 8B, illustrates and describes an example of a state after the photo resist layer 820 is removed. A photo resist removal process may be used to remove the photo resist layer 820.

The method removes (at 930) the sacrificial layer. Stage 6 of FIG. 8C, illustrates and describes an example of a state after the sacrificial layer 810 is removed. A photo resist removal process may be used to remove the sacrificial layer 810.

The method removes (at 935) portions of the seed layer. Stage 7 of FIG. 8C, illustrates and describes an example of a state after portions of the seed layer 801 are removed. An etching process may be used to remove portions of the seed layer 801. The remaining seed layer 801 may considered part of the plurality of spring pads 526 and/or the plurality of bridge interconnects 622.

### Exemplary Sequence for Fabricating a Substrate

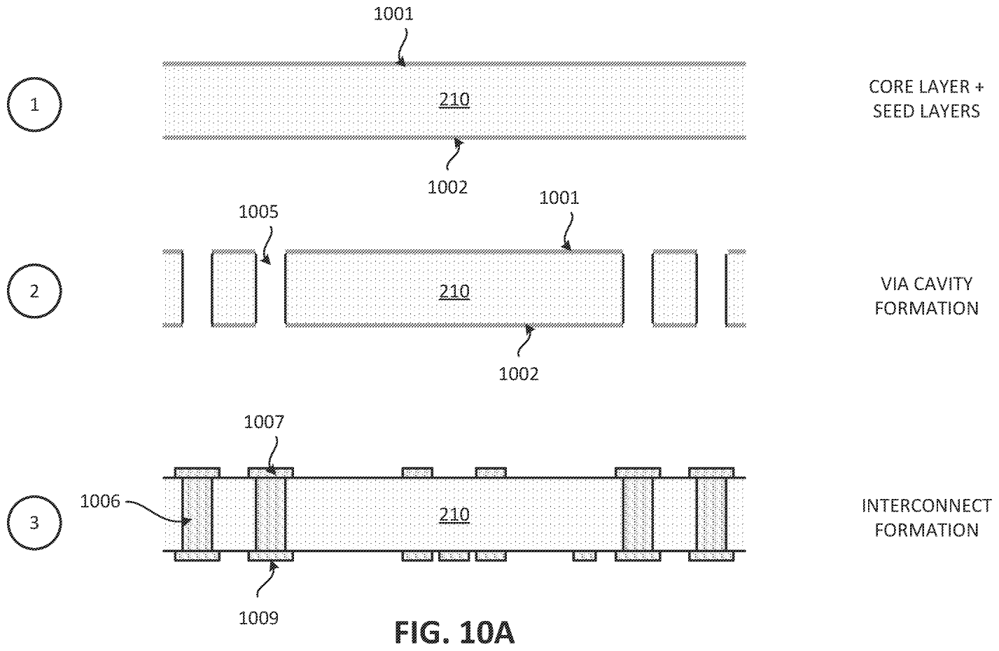

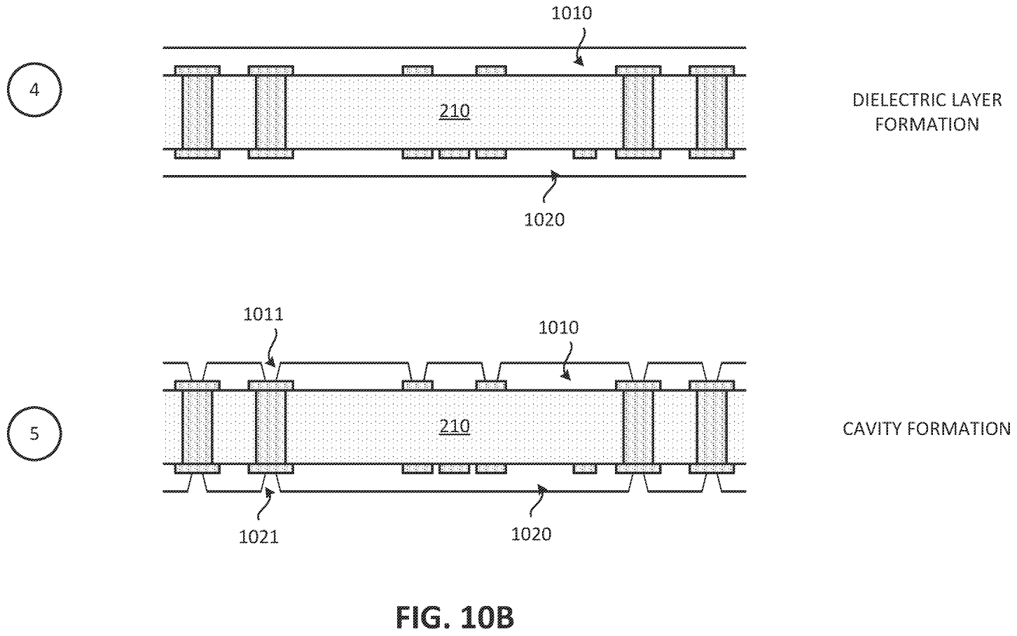

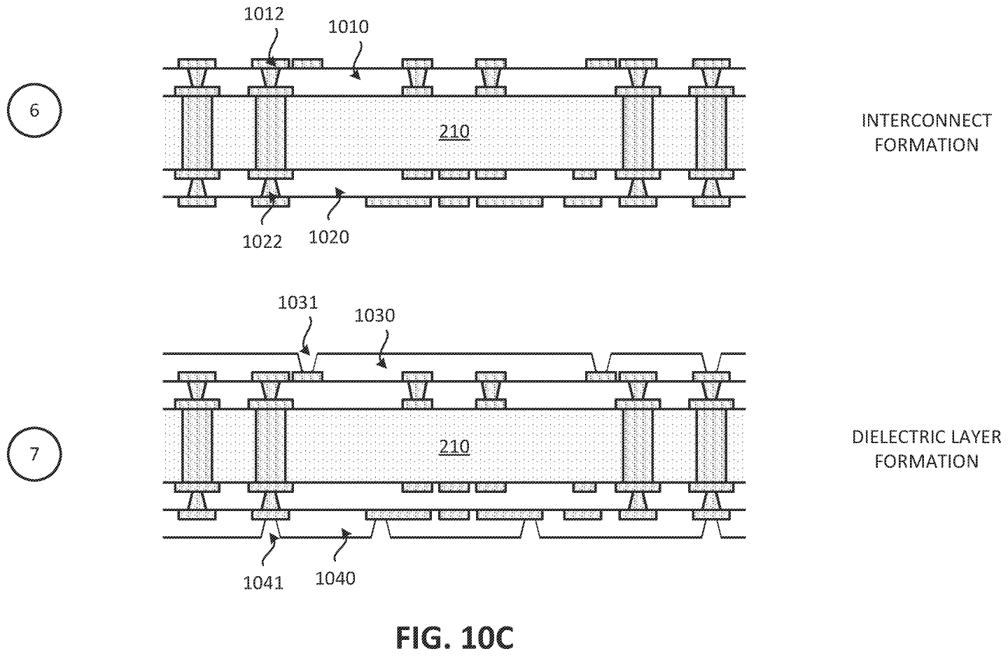

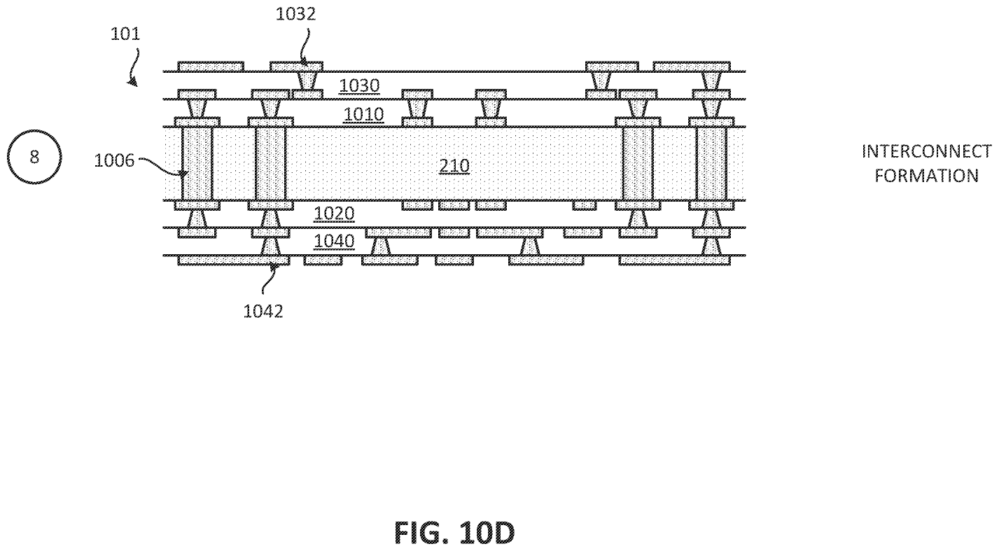

In some implementations, fabricating a substrate includes several processes. FIGS. 10A-10D illustrate an exemplary sequence for providing or fabricating a substrate. In some implementations, the sequence of FIGS. 10A-10D may be used to provide or fabricate the substrate 101. However, the process of FIGS. 10A-10D may be used to fabricate any of the substrates described in the disclosure.

It should be noted that the sequence of FIGS. 10A-10D may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.
Stage 1, as shown in FIG. 10A, illustrates a state after a core layer 210 and seed layers are provided. The seed layer 1001 is coupled to a first surface of the core layer 210. The seed layer 1002 is coupled to a second surface of the core layer 210. The seed layer 1001 and/or the seed layer 1002 may include copper. The core layer 210 may be a dielectric layer.
Stage 2 illustrates a state after a plurality of cavities 1005 are formed through the seed layer 1001, the core layer 210 and the seed layer 1002. A laser ablation process may be used to form the plurality of cavities 1005.
Stage 3 illustrates a state after a plurality of interconnects 1006, a plurality of interconnects 1007 and a plurality of interconnects 1009 are formed. The plurality of interconnects 1006 may be formed in the plurality of cavities 1005 of the core layer 210. A pasting process and/or a plating process may be used to form the plurality of interconnects 1006. The plurality of interconnects 1007 may be formed on the first surface of the core layer 210. A plating process may be used to form the plurality of interconnects 1007. The plurality of interconnects 1009 may be formed on the second surface of the core layer 210. A plating process may be used to form the plurality of interconnects 1009. The plurality of interconnects 1007 may be coupled to the plurality of interconnects 1006. The plurality of interconnects 1009 may be coupled to the plurality of interconnects 1006.
Stage 4, as shown in FIG. 10B, illustrates a state after a dielectric layer 1010 is formed and coupled to the first surface of the core layer 210 and the plurality of interconnects 1007. A deposition process and/or a lamination process may be used to form the dielectric layer 1010. Stage 4 also illustrates a state after a dielectric layer 1020 is formed and coupled to the second surface of the core layer 210 and the plurality of interconnects 1009. A deposition process and/or a lamination process may be used to form the dielectric layer 1020.
Stage 5 illustrates a state after a plurality of cavities 1011 are formed in the dielectric layer 1010 and a plurality of cavities 1021 are formed in the dielectric layer 1020. An exposure process and/or a development process may be used to form the plurality of cavities 1011 and/or the plurality of cavities 1021. The plurality of cavities 1011 and/or the plurality of cavities 1021 may be openings in the dielectric layer(s).
Stage 6, as shown FIG. 10C illustrates a state after a plurality of interconnects 1012 and a plurality of interconnects 1022 are formed. A plating process may be used to form the plurality of interconnects 1012 and the plurality of interconnects 1022. The plurality of interconnects 1012 are coupled to the plurality of interconnects 1007. The plurality of interconnects 1012 are coupled to the plurality of interconnects 1009.
Stage 7 illustrates a state after a dielectric layer 1030 and a dielectric layer 1040 are formed. The dielectric layer 1030 may include a plurality of cavities 1031. The dielectric layer 1040 may include a plurality of cavities 1041. The dielectric layer 1030 may be coupled to the dielectric layer 1010. The dielectric layer 1040 may be coupled to the dielectric layer 1020. A deposition process, a lamination process, an exposure process and/or a development process may be used to form the dielectric layer 1030 comprising a plurality of cavities 1031. A deposition process, a lamination process, an exposure process and/or a development process may be used to form the dielectric layer 1040 comprising a plurality of cavities 1041.
Stage 8, as shown FIG. 10D illustrates a state after a plurality of interconnects 1032 and a plurality of interconnects 1042 are formed. A plating process may be used to form the plurality of interconnects 1032 and the plurality of interconnects 1042. The plurality of interconnects 1032 are coupled to the plurality of interconnects 1012. The plurality of interconnects 1042 are coupled to the plurality of interconnects 1022. Stage 8 may illustrate a substrate 101.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Package Comprising a Substrate, a Bridge and Integrated Devices

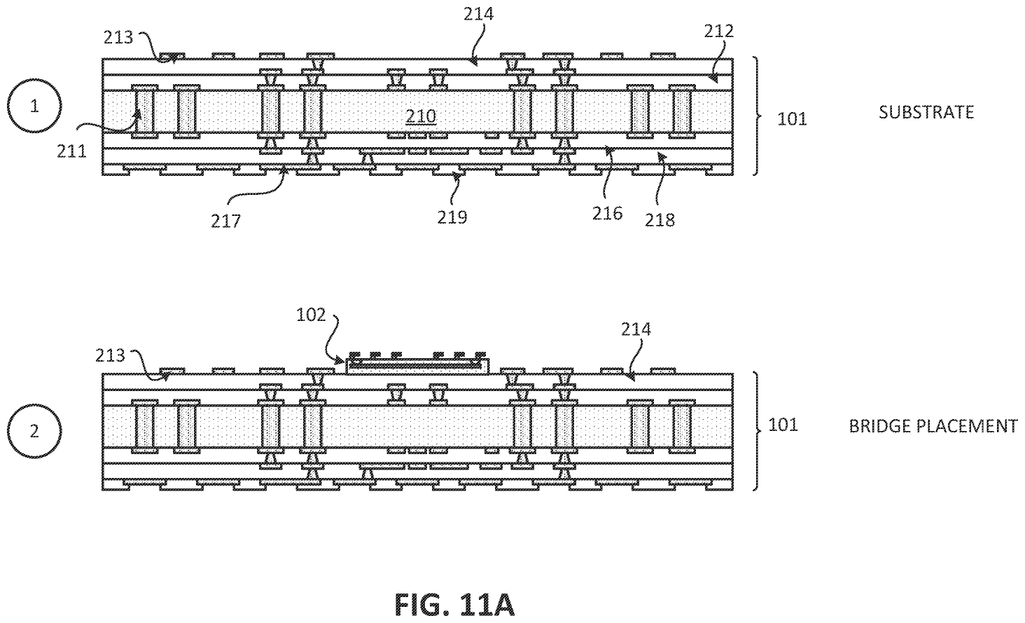

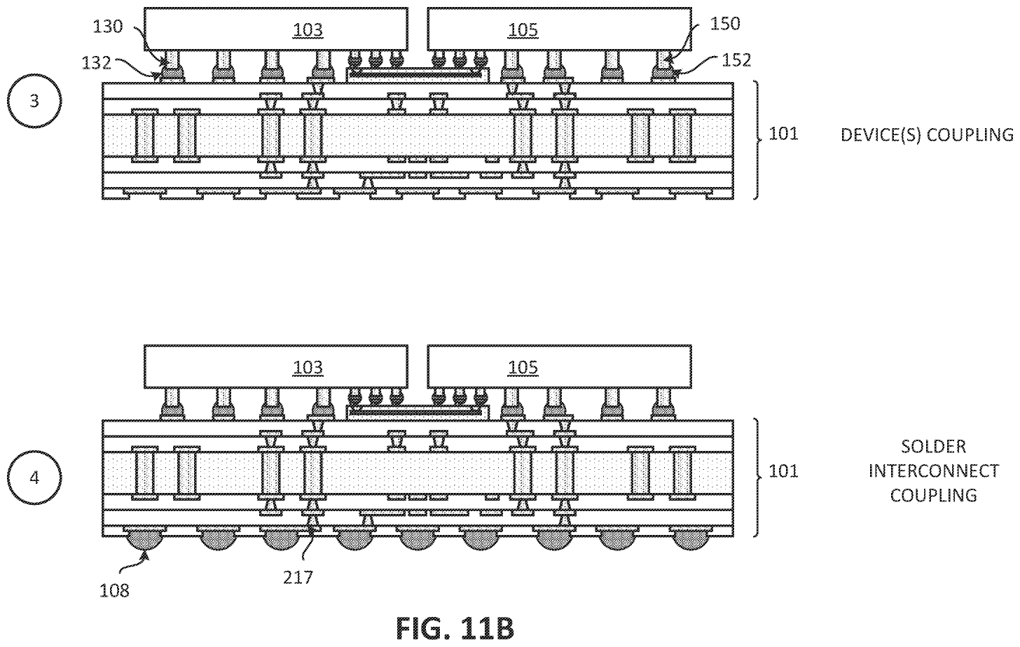

In some implementations, fabricating a package includes several processes. FIGS. 11A-11B illustrate an exemplary sequence for providing or fabricating a package. In some implementations, the sequence of FIGS. 11A-11B may be used to provide or fabricate the package 100. However, the process of FIGS. 11A-11B may be used to fabricate any of the packages (e.g., 300) described in the disclosure.

It should be noted that the sequence of FIGS. 11A-11B may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.
Stage 1, as shown in FIG. 11A, illustrates a state after a substrate 101 is provided. The substrate 101 includes a core layer 210, a dielectric layer 212, a dielectric layer 214, a dielectric layer 216, a dielectric layer 218, a solder resist layer 219, a plurality of interconnects 211, a plurality of interconnects 213 and a plurality of interconnects 217. FIGS. 10A-10D illustrate an example of a process for fabricating a substrate.
Stage 2 illustrates a state after a bridge 102 is placed and coupled to the substrate 101. An adhesive may be used to couple the back side of the bridge 102 to the substrate 101. In some implementations, the bridge 102 may be embedded in the substrate 101.
Stage 3, as shown in FIG. 11B, illustrates a state after the integrated device 103 is coupled to the substrate 101 and the bridge 102. The integrated device 103 is coupled to the substrate 101 and the bridge 102 through a plurality of pillar interconnects 130 and the plurality of solder interconnects 132. The integrated device 103 may be coupled to the spring pads of the bridge 102 through the plurality of pillar interconnects 130 and the plurality of solder interconnects 132. The integrated device 103 may be coupled to the plurality of interconnects (e.g., 112, 213) of the substrate 101 through a plurality of pillar interconnects 130 and the plurality of solder interconnects 132. A solder reflow process may be used to couple the integrated device 103 to the substrate 101 and the bridge 102.
Stage 3 also illustrates a state after the integrated device 105 is coupled to the substrate 101 and the bridge 102. The integrated device 105 is coupled to the substrate 101 and the bridge 102 through a plurality of pillar interconnects 150 and the plurality of solder interconnects 152. The integrated device 105 may be coupled to the spring pads of the bridge 102 through the plurality of pillar interconnects 150 and the plurality of solder interconnects 152. The integrated device 105 may be coupled to the plurality of interconnects (e.g., 112, 213) of the substrate 101 through a plurality of pillar interconnects 150 and the plurality of solder interconnects 152. A solder reflow process may be used to couple the integrated device 105 to the substrate 101 and the bridge 102.
Stage 4 illustrates a state after a plurality of solder interconnects 108 are coupled to the substrate 101. The plurality of solder interconnects 108 may be coupled to the plurality of interconnects 217 of the substrate 101. A solder reflow process may be used to couple the plurality of solder interconnects 108 to the substrate.

### Exemplary Flow Diagram of a Method for Fabricating a Package Comprising a Substrate, a Bridge and Integrated Devices

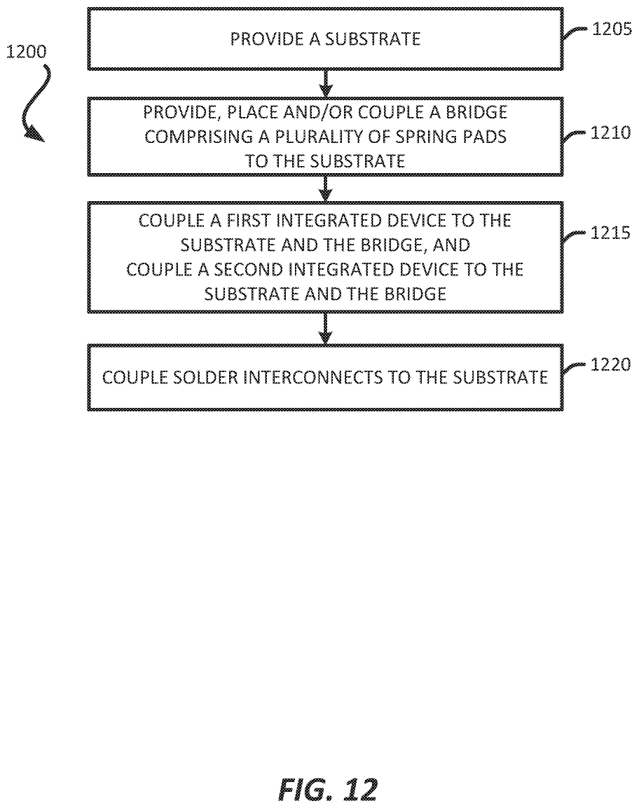

In some implementations, fabricating a package includes several processes. FIG. 12 illustrates an exemplary flow diagram of a method 1200 for providing or fabricating a package. In some implementations, the method 1200 of FIG. 12 may be used to provide or fabricate the package 100 described in the disclosure. However, the method 1200 may be used to provide or fabricate any of the packages (e.g., 300) described in the disclosure.

It should be noted that the method 1200 of FIG. 12 may combine one or more processes in order to simplify and/or clarify the method for providing or fabricating a package. In some implementations, the order of the processes may be changed or modified.

The method provides (at 1205) a substrate. Stage 1 of FIG. 11A, illustrates and describes an example of a state after a substrate 101 is provided. The substrate 101 includes a core layer 210, a dielectric layer 212, a dielectric layer 214, a dielectric layer 216, a dielectric layer 218, a solder resist layer 219, a plurality of interconnects 211, a plurality of interconnects 213 and a plurality of interconnects 217. FIGS. 10A-10D illustrate an example of a process for fabricating a substrate.

The method provides, places and couples (at 1210) a bridge to the substrate. The bridge may be coupled to a surface of the substrate. The bridge may be coupled and at least partially embedded in the substrate. Stage 2 of FIG. 11A, illustrates and describes an example of a state after a bridge 102 is placed and coupled to the substrate 101. An adhesive may be used to couple the back side of the bridge 102 to the substrate 101. In some implementations, the bridge 102 is embedded in the substrate 101.

The method couples (at 1215) a first integrated to the substrate and the bridge. The method also couples (at 1215) a second integrated to the substrate and the bridge. Stage 3 of FIG. 11B, illustrates and describes an example of a state after the integrated device 103 is coupled to the substrate 101 and the bridge 102. The integrated device 103 is coupled to the substrate 101 and the bridge 102 through a plurality of pillar interconnects 130 and the plurality of solder interconnects 132. The integrated device 103 may be coupled to the spring pads of the bridge 102 through the plurality of pillar interconnects 130 and the plurality of solder interconnects 132. The integrated device 103 may be coupled to the plurality of interconnects (e.g., 112, 213) of the substrate 101 through a plurality of pillar interconnects 130 and the plurality of solder interconnects 132. A solder reflow process may be used to couple the integrated device 103 to the substrate 101 and the bridge 102. Stage 3 also illustrates a state after the integrated device 105 is coupled to the substrate 101 and the bridge 102. The integrated device 105 is coupled to the substrate 101 and the bridge 102 through a plurality of pillar interconnects 150 and the plurality of solder interconnects 152. The integrated device 105 may be coupled to the spring pads of the bridge 102 through the plurality of pillar interconnects 150 and the plurality of solder interconnects 152. The integrated device 105 may be coupled to the plurality of interconnects (e.g., 112, 213) of the substrate 101 through a plurality of pillar interconnects 150 and the plurality of solder interconnects 152. A solder reflow process may be used to couple the integrated device 105 to the substrate 101 and the bridge 102.

The method couples (at 1220) a plurality of solder interconnects to the substrate. Stage 4 of FIG. 11B, illustrates and describes an example of a state after a plurality of solder interconnects 108 are coupled to the substrate 101. The plurality of solder interconnects 108 may be coupled to the plurality of interconnects 217 of the substrate 101. A solder reflow process may be used to couple the plurality of solder interconnects 108 to the substrate.

### Exemplary Electronic Devices

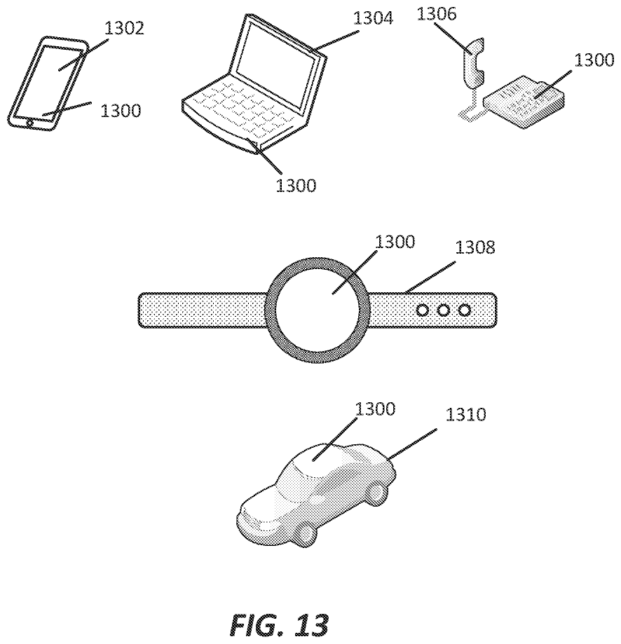

FIG. 13 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1302, a laptop computer device 1304, a fixed location terminal device 1306, a wearable device 1308, or automotive vehicle 1310 may include a device 1300 as described herein. The device 1300 may be, for example, any of the devices and/or integrated circuit (IC) packages described herein. The devices 1302, 1304, 1306 and 1308 and the vehicle 1310 illustrated in FIG. 13 are merely exemplary. Other electronic devices may also feature the device 1300 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-6, 7A-7C, 8A-8C, 9, 10A-10D, 11A-11B and 12-13 may be rearranged and/or combined into a single component, process, feature or function or embodied in several components, processes, or functions. Additional elements, components, processes, and/or functions may also be added without departing from the disclosure. It should also be noted FIGS. 1-6, 7A-7C, 8A-8C, 9, 10A-10D, 11A-11B and 12-13 and its corresponding description in the present disclosure is not limited to dies and/or ICs. In some implementations, FIGS. 1-6, 7A-7C, 8A-8C, 9, 10A-10D, 11A-11B and 12-13 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.
Aspect 1: A package comprising a substrate; a first integrated device coupled to the substrate through at least a first plurality of solder interconnects; a second integrated device coupled to the substrate through at least a second plurality of solder interconnects; and a bridge coupled to the substrate, wherein the bridge comprises a plurality of spring pads.
Aspect 2: The package of aspect 1, wherein the bridge is configured to be coupled to the first integrated device through at least a first set of spring pads from the plurality of spring pads, and wherein the bridge is configured to be coupled to the second integrated device through at least a second set of spring pads from the plurality of spring pads.
Aspect 3: The package of aspects 1 through 2, wherein the bridge is coupled to a surface of the substrate.
Aspect 4: The package of aspects 1 through 2, wherein the bridge is at least partially embedded in the substrate.
Aspect 5: The package of aspects 1 through 4, wherein an electrical path between the first integrated device and the second integrated device includes the bridge.
Aspect 6: The package of aspects 1 through 5, wherein an electrical path between the first integrated device and the second integrated device includes the plurality of spring pads of the bridge.
Aspect 7: The package of aspects 1 through 6, wherein the first integrated device is coupled to the substrate through at least a first plurality of pillar interconnects and the first plurality of solder interconnects, and wherein the second integrated device is coupled to the substrate through at least a second plurality of pillar interconnects and the second plurality of solder interconnects.
Aspect 8: The package of aspect 7, wherein the bridge is configured to be coupled to the first integrated device through at least a first set of spring pads from the plurality of spring pads, a first set of solder interconnects from the first plurality of solder interconnects and a first set of pillar interconnects from the first plurality of pillar interconnects, and wherein the bridge is configured to be coupled to the second integrated device through at least a second set of spring pads from the plurality of spring pads, a first set of solder interconnects from the second plurality of solder interconnects and a first set of pillar interconnects from the second plurality of pillar interconnects.
Aspect 9: The package of aspects 1 through 8, wherein the bridge comprises: a silicon substrate; and a plurality of bridge interconnects coupled to the plurality of spring pads.
Aspect 10: The package of aspects 1 through 9, wherein the plurality of spring pads are flexible pads.
Aspect 11: The package of aspects 1 through 9, wherein at least one spring pad from the plurality of spring pads has a helix shape.
Aspect 12: A method for fabricating a package. The method provides a substrate. The method couples a bridge to the substrate, wherein the bridge comprises a plurality of spring pads. The method couples a first integrated device to the substrate through at least a first plurality of solder interconnects. The method couples a second integrated device to the substrate through at least a second plurality of solder interconnects.
Aspect 13: The method of aspect 12, wherein the bridge is configured to be coupled to the first integrated device through at least a first set of spring pads from the plurality of spring pads, and wherein the bridge is configured to be coupled to the second integrated device through at least a second set of spring pads from the plurality of spring pads.
Aspect 14: The method of aspects 12 through 13, wherein the bridge is coupled to a surface of the substrate.
Aspect 15: The method of aspects 12 through 13, wherein the bridge is at least partially embedded in the substrate.
Aspect 16: The method of aspects 12 through 15, wherein an electrical path between the first integrated device and the second integrated device includes the plurality of spring pads of the bridge.
Aspect 17: The method of aspects 12 through 16, wherein the first integrated device is coupled to the substrate through at least a first plurality of pillar interconnects and the first plurality of solder interconnects, and wherein the second integrated device is coupled to the substrate through at least a second plurality of pillar interconnects and the second plurality of solder interconnects.
Aspect 18: The method of aspect 17, wherein the bridge is configured to be coupled to the first integrated device through at least a first set of spring pads from the plurality of spring pads, a first set of solder interconnects from the first plurality of solder interconnects and a first set of pillar interconnects from the first plurality of pillar interconnects, and wherein the bridge is configured to be coupled to the second integrated device through at least a second set of spring pads from the plurality of spring pads, a first set of solder interconnects from the second plurality of solder interconnects and a first set of pillar interconnects from the second plurality of pillar interconnects.
Aspect 19: The method of aspects 12 through 18, wherein the plurality of spring pads are flexible pads.
Aspect 20: The method of aspects 12 through 19, wherein at least one spring pad from the plurality of spring pads has a helix shape.
Aspect 21: The package of aspects 1 through 11, wherein the package is implemented in a device that is selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a substrate;
a first integrated device coupled to the substrate through at least a first plurality of solder interconnects;
a second integrated device coupled to the substrate through at least a second plurality of solder interconnects; and
a bridge coupled to the substrate, wherein the bridge comprises a plurality of spring pads.

2. The package of claim 1,
wherein the bridge is configured to be coupled to the first integrated device through at least a first set of spring pads from the plurality of spring pads, and
wherein the bridge is configured to be coupled to the second integrated device through at least a second set of spring pads from the plurality of spring pads.

3. The package of claim 1, wherein the bridge is coupled to a surface of the substrate.

4. The package of claim 1, wherein the bridge is at least partially embedded in the substrate.

5. The package of claim 1, wherein an electrical path between the first integrated device and the second integrated device includes the bridge.

6. The package of claim 1, wherein an electrical path between the first integrated device and the second integrated device includes the plurality of spring pads of the bridge.

7. The package of claim 1,
wherein the first integrated device is coupled to the substrate through at least a first plurality of pillar interconnects and the first plurality of solder interconnects, and
wherein the second integrated device is coupled to the substrate through at least a second plurality of pillar interconnects and the second plurality of solder interconnects.

8. The package of claim 7,
wherein the bridge is configured to be coupled to the first integrated device through at least a first set of spring pads from the plurality of spring pads, a first set of solder interconnects from the first plurality of solder interconnects and a first set of pillar interconnects from the first plurality of pillar interconnects, and
wherein the bridge is configured to be coupled to the second integrated device through at least a second set of spring pads from the plurality of spring pads, a first set of solder interconnects from the second plurality of solder interconnects and a first set of pillar interconnects from the second plurality of pillar interconnects.

9. The package of claim 1, wherein the bridge comprises:
a silicon substrate; and
a plurality of bridge interconnects coupled to the plurality of spring pads.

10. The package of claim 1, wherein the plurality of spring pads are flexible pads.

11. The package of claim 1, wherein at least one spring pad from the plurality of spring pads has a helix shape.

12. A method for fabricating a package, comprising:
providing a substrate;
coupling a bridge to the substrate, wherein the bridge comprises a plurality of spring pads;
coupling a first integrated device to the substrate through at least a first plurality of solder interconnects; and
coupling a second integrated device to the substrate through at least a second plurality of solder interconnects.

13. The method of claim 12,
wherein the bridge is configured to be coupled to the first integrated device through at least a first set of spring pads from the plurality of spring pads, and
wherein the bridge is configured to be coupled to the second integrated device through at least a second set of spring pads from the plurality of spring pads.

14. The method of claim 12, wherein the bridge is coupled to a surface of the substrate.

15. The method of claim 12, wherein the bridge is at least partially embedded in the substrate.

16. The method of claim 12, wherein an electrical path between the first integrated device and the second integrated device includes the plurality of spring pads of the bridge.

17. The method of claim 12,
wherein the first integrated device is coupled to the substrate through at least a first plurality of pillar interconnects and the first plurality of solder interconnects, and
wherein the second integrated device is coupled to the substrate through at least a second plurality of pillar interconnects and the second plurality of solder interconnects.

18. The method of claim 17,
wherein the bridge is configured to be coupled to the first integrated device through at least a first set of spring pads from the plurality of spring pads, a first set of solder interconnects from the first plurality of solder interconnects and a first set of pillar interconnects from the first plurality of pillar interconnects, and
wherein the bridge is configured to be coupled to the second integrated device through at least a second set of spring pads from the plurality of spring pads, a first set of solder interconnects from the second plurality of solder interconnects and a first set of pillar interconnects from the second plurality of pillar interconnects.

19. The method of claim 12, wherein the plurality of spring pads are flexible pads.

20. The method of claim 12, wherein at least one spring pad from the plurality of spring pads has a helix shape.
